(19) United States
(12) Patent Application Publication
(10) Pub. No.: US 2015/0025362 A1
(43) Pub. Date: Jan. 22, 2015

(54) Local Transmission Coils and Transmission Coil Arrays for Spinal Column Imaging in an MRI Device

(71) Applicants: Stephan Biber, Erlangen (DE); Hubertus Fischer, Bamberg (DE); Helmut Greim, Adelsdorf (DE)

(72) Inventors: Stephan Biber, Erlangen (DE); Hubertus Fischer, Bamberg (DE); Helmut Greim, Adelsdorf (DE)

(21) Appl. No.: 14/337,728

(22) Filed: Jul. 22, 2014

(30) Foreign Application Priority Data
Jul. 22, 2013 (DE) 102013214307.9

(51) Int. Cl. G01R 33/34

(52) U.S. Cl. CPC G01R 33/34
USPC 600/422

(57) ABSTRACT

A spine coil for a magnetic resonance imaging device includes at least one transmission coil element configured for transmission.

### RELATED APPLICATIONS

This application claims the benefit of German Patent Application No. DE 102013214307.9, filed Jul. 22, 2013. The entire contents of the priority document are hereby incorporated herein by reference.

### TECHNICAL FIELD

The present teachings relate generally to methods and devices for magnetic resonance imaging (MRI).

### BACKGROUND

Magnetic resonance imaging (MRI) devices for examining objects and/or patients using magnetic resonance imaging are described, for example, in DE 10314215B4.

### SUMMARY AND DESCRIPTION

The scope of the present invention is defined solely by the appended claims, and is not affected to any degree by the statements within this summary.

In some embodiments, a procedure for optimizing magnetic resonance imaging is provided.

### BRIEF DESCRIPTION OF THE DRAWINGS

FIG. 1 shows a cross-sectional view in a y, z-plane of an example of a spine coil with coil elements configured for transmission and coil elements configured for reception.

FIG. 2 shows a cross-sectional view in an x, z-plane of an example of a spine coil with coil elements configured for transmission.

FIG. 3 shows schematic illustrations of exemplary connections between transmission coil elements and a transmission apparatus.

FIG. 4 shows a schematic illustration of three different examples of a coil element.

FIG. 5 shows schematic illustrations of different examples of coil elements.

FIG. 6 shows a schematic illustration of an MRI system.

### DETAILED DESCRIPTION

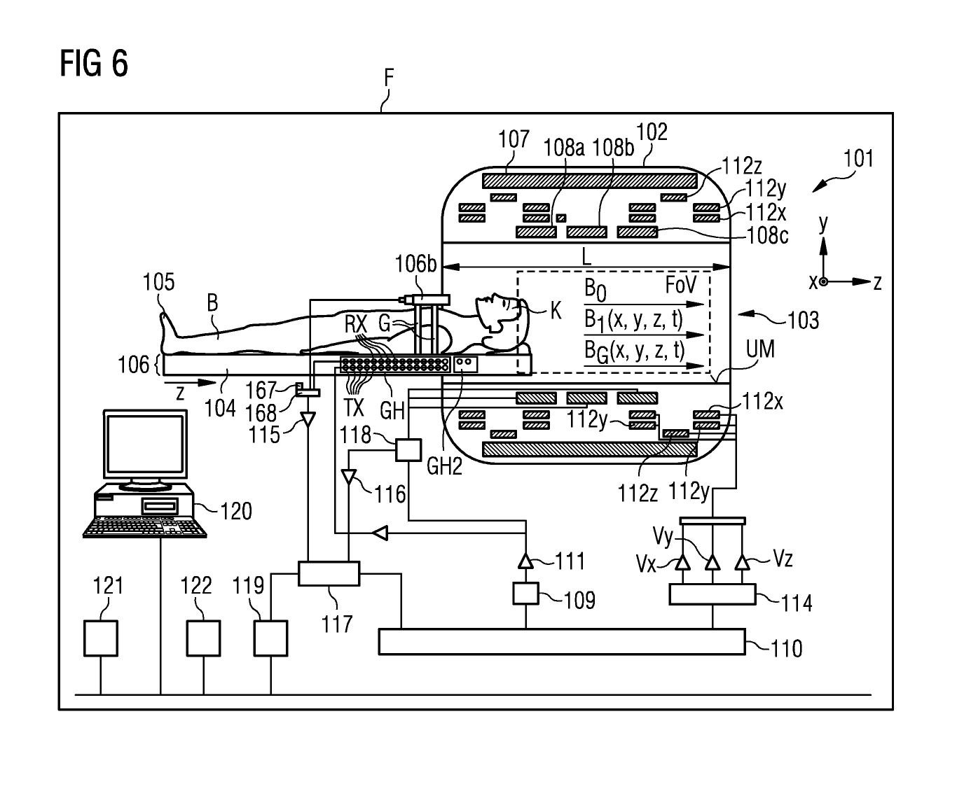

FIG. 6 shows a magnetic resonance imaging (MRI) device 101 in a shielded room or Faraday cage F. The device 101 includes a whole body coil 102 that, in some embodiments, includes a tubular space 103. A patient couch 104 with an examination object 105 (e.g., a patient), with or without local coil arrangement 106, may be displaced in the direction of the arrow z to generate recordings of the patient 105 by an imaging method. In some embodiments, a local coil arrangement 106 is arranged on the patient. Recordings of a portion of the body 105 in a local region of the MRI (also referred to as field of view or FOV) may be generated by the local coil arrangement. Signals from the local coil arrangement 106 may be evaluated (e.g., converted into images, stored, or displayed) by an evaluation device (168, 115, 117, 119, 120, 121, etc.) of the MRI 101. The evaluation device may be connected to the local coil arrangement 106 by, for example, coaxial cables, a radio link 167, or the like.

In order to use a MRI device 101 to examine a body 105 (e.g., an examination object or a patient) by magnetic resonance imaging, different magnetic fields that are matched to one another in temporal and spatial characteristics are radiated onto the body 105. A strong magnet (e.g., a cryomagnet 107) in a measurement cabin with an opening 103 that, in some embodiments, is tunnel-shaped may generate a strong static main magnetic field B₀ (e.g., having a strength of 0.2 Tesla to 3 Tesla or greater). A body 105 to be examined is supported by a patient couch 104 and driven into a region of the main magnetic field B₀ that is substantially homogeneous in the observation region field of view (FOV). The nuclear spins of atomic nuclei of the body 105 are excited by magnetic radiofrequency excitation pulses B1 (x, y, z, t) that are radiated by a radiofrequency antenna (and/or, optionally, a local coil arrangement). The radiofrequency antenna is depicted in a greatly simplified manner as a multi-part body coil 108 (e.g., 108a, 108b, 108c). By way of example, radiofrequency excitation pulses are generated by a pulse generation unit 109 that is controlled by a pulse sequence control unit 110. After amplification by a radiofrequency amplifier 111, the radiofrequency excitation pulses are conducted to the radiofrequency antenna 108. The radiofrequency system is shown schematically in FIG. 7. In a magnetic resonance imaging device 101, more than one pulse generation unit 109, more than one radiofrequency amplifier 111, and more than one radiofrequency antenna 108a, 108b, 108c may be used.

The magnetic resonance imaging device 101 further includes gradient coils 112x, 112y, 112z. Magnetic gradient fields B_{G} (x, y, z, t) are radiated by the gradient coils during a measurement for selective slice excitation and for spatial encoding of the measurement signal. The gradient coils 112x, 112y, 112z are controlled by a gradient coil control unit 114 (and, optionally, via amplifiers Vx, Vy, Vz). The gradient coil control unit 114, like the pulse generation unit 109, is connected to the pulse sequence control unit 110.

Signals emitted by the excited nuclear spins (e.g., of the atomic nuclei in the examination object) are received by the body coil 108 and/or at least one local coil arrangement 106. The signals are amplified by associated radiofrequency preamplifiers 116 and further processed and digitized by a reception unit 117. The recorded measurement data are digitized and stored as complex numbers in a k-space matrix. An associated MRI image may be reconstructed from the k-space matrix filled with values by a multidimensional Fourier transform.

For a coil that may be operated in both transmission mode and in reception mode (e.g., the body coil 108 or a local coil 106), the correct signal transmission is regulated by an upstream transmission/reception switch 118.

An image-processing unit 119 generates an image from the measurement data that is displayed to a user by an operating console 120 and/or stored in a storage unit 121. A central computer unit 122 controls the individual installation components.

In MR imaging, images with a high signal-to-noise ratio (SNR) may be recorded using local coil arrangements (e.g., coils, local coils). Local coil arrangements are antenna systems that are attached in the direct vicinity on (anterior) or under (posterior), or at or in, the body 105. During an MR measurement, the excited nuclei induce a voltage in the individual antennae (also referred to as coil elements) of the local coil. The voltage is then amplified using a low-noise preamplifier (e.g., LNA, preamp) and transmitted to the reception electronics. In order to improve the signal-to-noise ratio even for high-resolution images, high-field installations (e.g., 1.5 Tesla to 12 Tesla or greater) may be used. If more individual antennae are connected to an MR reception system than there are receivers available, a switching matrix (also referred to as RCCS) may be installed between the reception antennae and receivers. The matrix routes the currently active reception channels (e.g., the channels that currently lie in the field of view of the magnet) to the available receivers. As a result, more coil elements may be connected than there are receivers available because, in the case of a whole body cover, only coils that are situated in the FOV or in the homogeneity volume of the magnet are read.

By way of example, an antenna system that may include one antenna element or, as an array coil, several antenna elements (e.g., coil elements) may be referred to as a local coil arrangement 106. In some embodiments, these individual antenna elements may be embodied as loop antennae (loops), butterfly coils, flex coils, or saddle coils. In some embodiments, a local coil arrangement includes coil elements, a preamplifier, additional electronics (e.g., standing wave traps, etc.), a housing, and supports. The local coil arrangement may also include a cable with a plug for connecting to the MRI installation. A receiver 168 attached to the installation side filters and digitizes a signal received from a local coil 106 (e.g., by radio link, etc.) and transmits the data to a digital signal-processing device. The digital signal-processing device may derive an image or a spectrum from the data obtained by a measurement and makes the image or spectrum available to the user (e.g., for subsequent diagnosis by the user and/or for storing).

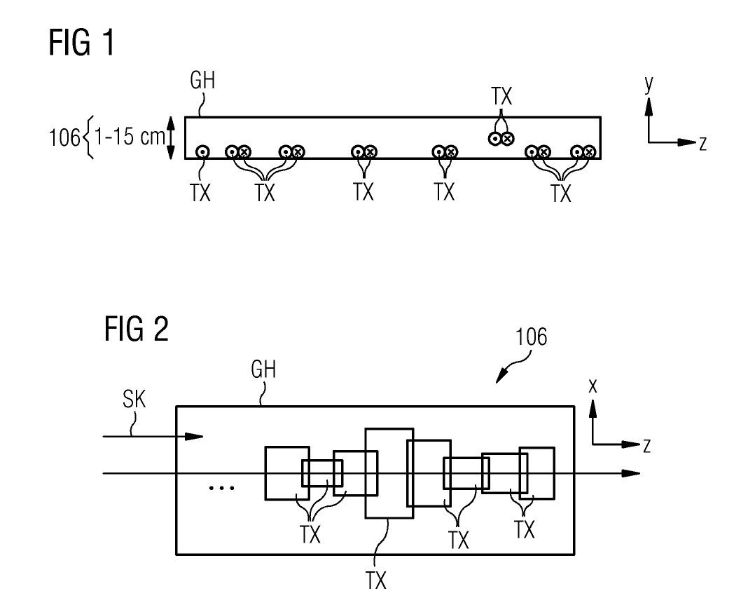

FIGS. 1-5 show examples of transmission elements and spine coils in accordance with the present teachings.

By using local transmission coils 106 (e.g., local coils or LC) in magnetic resonance imaging, higher B1 peak values (e.g., magnitude maxima) and higher B1 average values (e.g., mean values) may be achieved. Applications that involve high B1 values over a short time (e.g., short echo times, “metal imaging” for suppressing artifacts on implants, spectroscopy) may benefit from higher B1 peak values. Moreover, local transmission coils may limit the specific absorption rate (SAR) by applying the transmission field to only a dedicated part of the body 105 (e.g., the left knee) rather than onto a whole body 105 situated in the body coil 103 of an MRI device. Moreover, limiting the transmission field and a different field profile may provide design advantages (e.g., in the direction of phase encoding) if convolutions from other body parts that are not intended for examination may be suppressed more strongly (e.g., since no transmission field acts on the body parts). By way of example, a phase encoding direction in the z-direction may use less phase oversampling in knee or head imaging since the irradiation of a local knee or head coil may be lower in the z-direction. These advantages may apply to transmission coils transmitting both on one channel and on a plurality of channels.

However, for locally transmitting coils 106, the use of a locally strongly restricted and, in some embodiments, slightly more inhomogeneous transmission field of a local coil 106 may not suffice for all examinations. By way of example, if a cervical spine examination is to be carried out following a head examination using a local transmission coil, interchanging of the coils and repositioning of the patient may be involved.

Local transmission coils may provide one or more of the following: (a) a higher B1 field peak (e.g., for suppressing B0 artifacts of metal implants by very short and/or very high/strong B1 pulses); (b) a lower global SAR; (c) a lower local SAR resulting from the ease of placing a transmission coil TX slightly further away from the tissue of an examination object 105 to be examined as compared to using a body coil BC (e.g., 108a, 108b, 108c), thereby making the BC a more expensive option vis-à-vis magnet diameter; and (d) a stronger localization of field profiles for more expedient protocol selection or improved orthogonality of the TX profiles (pTX).

Orthopedic questions may arise, and patients with metal implants (e.g., screws, metal tissue, “cages”, etc.) may be examined (e.g., in the region of the spinal column). The very high B1 peak values involved in these examinations may not be easy to achieve by a body coil (BC) 108a, 108b, 108c. For example, obstacles may lie in the high transmission power used, the dielectric strength of the body coil BC (e.g., 108a, 108b, 108c), and the SAR limits of the patient 105.

Heretofore, locally transmitting coils have not been used in the region of the spinal column. A concern is that B1 pulse amplitudes (e.g., 25-70 μT, for example, 33-55 μT) used to suppress metal artifacts may not be reached in this body region (as opposed to, for example, the knee, where locally transmitting coils are available). During operation with a body coil BC, the high peak amplitudes may not be reached since either of a very high peak power from the transmitter or a very high efficiency of the body coil BC may be technically difficult and expensive to achieve. Moreover, transmission amplitude may be limited by SAR limits. These limitations may be circumvented or improved with the aid of a local transmission coil.

A solution in accordance with the present teachings will now be described. A plurality of coil elements TX may be used for transmission and arranged in the housing GH of a spine coil 106 (also referred to below as spine RX coil) or in a housing GH2 separate from the housing GH. Staggering the coil elements TX in the z-direction (e.g., the longitudinal direction of the spine coil and/or the longitudinal direction of the bore 103) may facilitate application of a transmission field (e.g., RF and/or gradient) to only the body region of an examination object 105 wherein the region of interest (ROI) is situated. For example, in the case of metal imaging of a spinal column, the ROI may be one or a few vertebrae.

Each of the coil elements TX, RX staggered in the z-direction may be decoupled from the coil element's direct neighbors and may also be decoupled from the coil element's more distant neighbors (e.g., the neighbors of the coil element's direct neighbors) by inductive or capacitive decoupling and/or by external wiring (e.g., within the local coil or external therefrom). In some embodiments, the coil elements for transmission TX (e.g., transmission coil elements) may optionally also be used as reception elements RX (e.g., reception coil elements).

In some embodiments, the spine coil 106 is a TX-RX hybrid coil. The reception coil elements RX are situated close to the surface (e.g., near the examination object) of the spine coil 106, and the transmission coil elements TX are situated slightly further away (e.g., by 1-7 cm). An advantage of the slightly further distance of the transmission coil elements TX (e.g., when positioned on the posterior side of the spine coil 106 or in a separate housing GH2 under the RX spine coil 106) may lay in an improved B1 homogeneity in the ROI. The RX elements may remain close to the patient in configurations, for example, wherein the TX (transmission) and RX (reception) functions are realized in separate antenna structures.

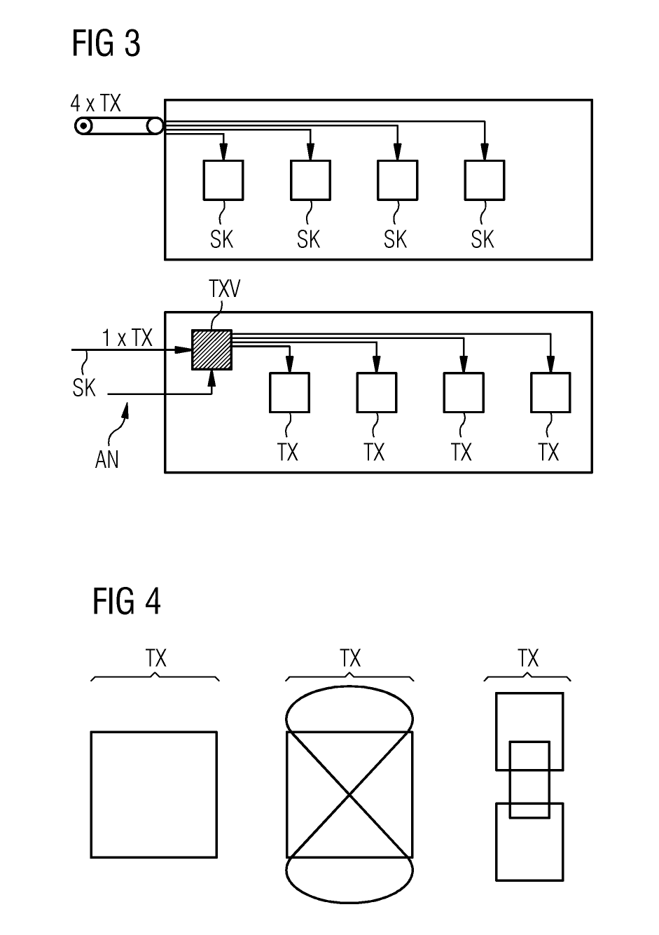

Transmission power (e.g., TX power) may be applied individually or separately to the transmission coil elements TX. Switching from the transmitter (e.g., 109) to one or more transmission coil elements TX may be performed, for example, by a TX switching matrix TXV, as shown at the bottom of FIG. 3. The TXV may be integrated in the MRI system or in the spine coil 106. Alternatively, or in addition, switching from the transmitter (e.g., 109) to one or more transmission coil elements TX may be performed by actuating the transmitter belonging to the transmission coil element TX if there is a plurality of transmitter/transmission coil element connections 4×TX.

A switching matrix TXV may permit the distribution of the transmission power from N transmitters to M coil elements TX (e.g., wherein M is equal or unequal to N). A local coil 106 and/or 106b may be detuned, such that only the body coil BC (108a, 108b, 108c) may be operated as a transmission coil when the spine TX coil 106 is present.

Antenna arrangements that generate a homogenous field in the region of the spinal column 106 may be advantageous. By way of example, an antenna arrangement configured to generate a homogenous field in the region of the spinal column may be implemented by selecting the dimensions of the transmission coil elements TX. In order to take account of the varying depth in the body (e.g., in the vertical direction y) of the spinal column of an examination object 105, the transmission coil elements TX may be selected with different dimensions in the z-direction. In addition, the transmission coil elements TX may be embodied, for example, as a loop-butterfly combination. As a result of the loop-butterfly combination, the transmission (TX) field homogeneity may be optimized in the region of the spinal column when the antennae TX are suitably dimensioned. A loop-butterfly combination of a transmission coil element TX may be fed from a transmitter (e.g., 109) by a power splitter and/or a phase shifter.

In some embodiments, one or more transmission coil elements (TX) that are integrated in a spine coil may be configured to excite dedicated regions of the spinal column of an examination object 103 and to generate high B1 peak amplitudes and a sufficient homogeneity. This configuration may support the implementation of applications involving high B1 peak fields. Thus, in some embodiments, higher B1 fields may be generated than with a body coil BC even though relatively little transmission power is used. Moreover, such a configuration may have more expedient SAR properties than a body coil 108a, 108b, 108c.

Further details of embodiments in accordance with the present teachings will now be described in reference to FIGS. 1-5.

FIG. 1 shows a cross-sectional view of a spine coil 106 in a y, z-plane (e.g., in the longitudinal direction z of the bore and cut in a vertical plane). The spine coil 106 may have a thickness, for example, of 1-15 cm in the x-direction and transmission coil elements TX that are configured for transmission. As shown in FIG. 1, at least a portion of the transmission coil elements may be at different heights (e.g., in the vertical direction x, perpendicularly upward from the ground).

By way of example, as shown in FIG. 6, a spine coil 106 and/or the housing GH of the spine coil 106 may be arranged in a recess of a patient couch 104.

FIG. 2 shows a cross-sectional view of the spine coil 106 in an x, z-plane (e.g., in the longitudinal direction z of the bore and cut in a horizontal plane). The spine coil 106 includes transmission coil elements TX configured for transmission.

As shown in FIG. 2, the transmission coil elements TX of the spine coil 106 may be arranged symmetrically. Alternatively, or in addition, each of the transmission coil elements TX may be arranged centrally with respect to the z, y-plane (e.g., extending vertically and in the longitudinal direction of the spine coil).

In some embodiments, the transmission coil elements TX have different dimensions in the x, z-direction and/or in terms of width and/or length. In some embodiments, the dimensions may be dependent on position in the spine coil in the z-direction (e.g., broader dimensions in the region of the pelvis than in the region of the neck). Spatial positioning in the spine coil and geometric configurations of coil elements TX (e.g., with respect to length in the direction z and width in the direction x) may be selected to optimize the shaping of the B1 field distribution within the FOV (e.g., for imaging a spinal column).

By way of example, variations to the configuration illustrated in FIG. 2 may include one or more of the following: (a) a plurality of coil elements TX may be arranged next to one another (e.g., in the x-direction horizontally and orthogonally with respect to the longitudinal axis of the spine coil 106); (b) transmission coil elements TX configured for transmission and reception coil elements RX configured for reception may be arranged in the spine coil 106; (c) coil elements TX configured for transmission and/or coil elements RX configured for reception may have common antenna structures; and (d) at least a portion of the coil elements RX configured for reception may also be used for transmission (e.g., coil elements RX in a central plane, such as those in the center of FIG. 2).

The top illustration in FIG. 3 depicts an example of a connection between the transmission coil elements TX and a transmission apparatus (e.g., 109) with a transmission power distribution to four separate transmission lines (TX lines) 4×TX. Each of the transmission lines is between one or more coil elements TX and a transmission apparatus.

The bottom illustration in FIG. 3 depicts an example of a connection between the transmission coil elements TX and a transmission apparatus (e.g., 109). There is only only one common transmission line (TX line, 1×TX) between the coil elements TX in the spine coil 106 and the transmission apparatus. In such a configuration, a transmission power distribution circuit TXV may be used to split the transmission power to a plurality of coil elements TX (e.g., in accordance with inputs from a control unit via an actuation line AN and, for example, in accordance with amplitude and/or phase).

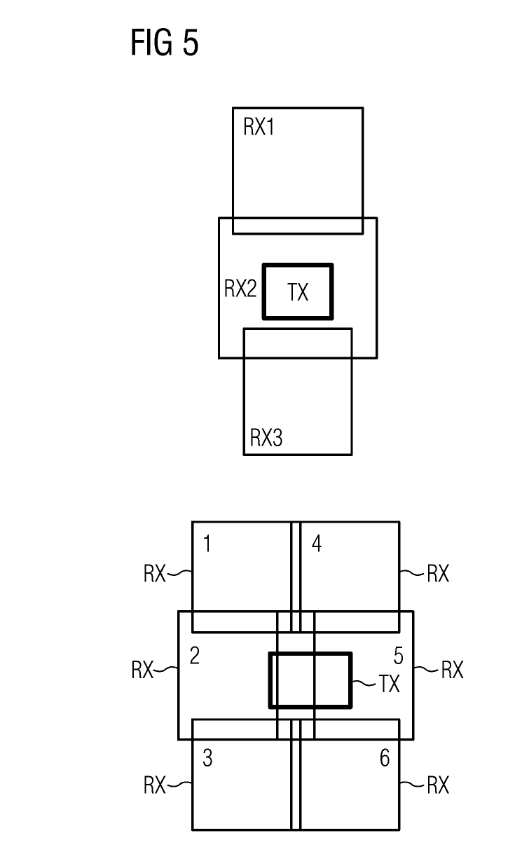

FIG. 4 shows three different transmission coil elements TX. The left-hand drawing in FIG. 4 shows a transmission coil element TX in the form of a rectangular loop (also referred to as loop). The central drawing in FIG. 4 shows a combined transmission coil element TX with a rectangular loop and a butterfly coil (e.g., to generate a relatively strong, circularly polarized field at a certain depth y in the patient and/or to optimize the B1 homogeneity). The right-hand drawing in FIG. 4 shows a transmission coil element TX that includes a plurality of rectangular, overlapping individual elements.

FIG. 5 shows a plurality of examples of different configurations of coil elements TX and/or RX for clarifying variants of TX/RX decoupling.

Even if ideal decoupling of an RX/TX array (e.g., separated antenna elements) may not be achieved, partial decoupling may be used for coupling the transmission power (TX power) into the detuning circuit of an RX element in a reduced manner and/or for distributing the transmission power in an improved manner. As a result, the load on detuning circuits (e.g., with respect to peak voltage and temperature) may be reduced and/or distributed in an improved manner.

The top drawing in FIG. 5 shows coil elements TX and RX2 that may be coupled to one another relatively strongly. By contrast, the bottom drawing in FIG. 5 shows coil elements TX and RX2, RX5 that are weakly coupled.

Coil elements TX configured for transmission and coil elements RX configured for reception may also have a spatial offset from one another in the x-direction (e.g., horizontally and transversely to the longitudinal direction z of the spine coil). In other words, the coil elements TX configured for transmission and the coil elements RX configured for reception may be displaced with respect to one another (e.g., with spacing and/or without overlap and/or with partial overlap).

While the present invention has been described above by reference to various embodiments, it should be understood that many changes and modifications may be made to the described embodiments. It is therefore intended that the foregoing description be regarded as illustrative rather than limiting, and that it be understood that all equivalents and/or combinations of embodiments are intended to be included in this description.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding claim—whether independent or dependent—and that such new combinations are to be understood as forming a part of the present specification.

1. A spine coil for a magnetic resonance imaging device, the spine coil comprising:
at least one transmission coil element configured for transmission.

2. The spine coil of claim 1, wherein the spine coil comprises a plurality of transmission coil elements.

3. The spine coil of claim 2, further comprising a first housing, wherein one or more of the plurality of transmission coil elements is provided within the first housing.

4. The spine coil of claim 3, further comprising a second housing, wherein one or more of the plurality of transmission coil elements is provided in the second housing and outside the first housing.

5. The spine coil of claim 2, wherein each transmission coil element of the plurality of transmission coil elements is (a) arranged in succession along a longitudinal direction of a bore of a magnetic resonance imaging device, (b) arranged along a longitudinal direction of a patient couch, the spine coil being arranged on or in the patient couch, or (c) arranged in succession along the longitudinal direction of the bore and along the longitudinal direction of the patient couch.

6. The spine coil of claim 2, wherein each transmission coil element of the plurality of transmission coil elements is arranged in succession along one direction, and wherein each transmission coil element of the plurality of transmission coil elements is (a) individually actuatable for transmission, (b) configured to be connected to, or connected to, a transmission apparatus by one or a plurality of dedicated transmission cables, or (c) individually actuatable for transmission and configured to be connected to, or connected to, the transmission apparatus by the one or the plurality of dedicated transmission cables.

7. The spine coil of claim 2, wherein each transmission coil element of the plurality of transmission coil elements is actuatable by a common transmission cable, the common transmission cable being configured for connection to, or connected to, a transmission apparatus, wherein the spine coil is configured to split transmission power transmitted by the common transmission cable to an individual transmission coil element of the plurality of transmission coil elements.

8. The spine coil of claim 2, wherein each transmission coil element of the plurality of transmission coil elements is arranged in succession along a direction of an axis in a configuration that is mirror symmetric with respect to the axis in the spine coil.

9. The spine coil of claim 2, wherein transmission coil elements of the plurality of transmission coil elements have different dimensions in a first direction, the first direction being horizontal and perpendicular to a longitudinal direction, or different dimensions in a first direction and a second direction, the first direction and the second direction being perpendicular to one another and to the longitudinal direction.

10. The spine coil of claim 2, wherein the transmission coil elements of the plurality of transmission coil elements are arranged next to one another in one or two directions that are perpendicular and horizontal to a longitudinal axis of the spine coil.

11. The spine coil of claim 5, wherein a plurality of the plurality of transmission coil elements are (a) decoupled from directly adjacent transmission coil elements, (b) decoupled from transmission coil elements adjacent to the directly adjacent transmission coil elements, or (c) decoupled from directly adjacent transmission coil elements and transmission coil elements adjacent to the directly adjacent transmission coil elements, wherein decoupling is achieved by inductive decoupling, external wiring, or inductive decoupling and external wiring.

12. The spine coil of claim 2, wherein at least a portion of the plurality of transmission coil elements is configured for transmission and reception, and is connected to a transmitter and a receiver.

13. The spine coil of claim 2, wherein at least a first portion of the plurality of transmission coil elements is configured for only transmission, the first portion being connected to a transmission apparatus of a magnetic resonance imaging device, and wherein at least a second portion of the plurality of transmission coil elements is configured for only reception, the second portion being connected to a reception apparatus of the magnetic resonance imaging device.

14. The spine coil of claim 13, wherein the first portion is offset in a longitudinal direction of the spine coil relative to the second portion.

15. The spine coil of claim 13, wherein the first portion is connected to the transmission apparatus by a transmission distribution circuit, and wherein the transmission distribution circuit is actuatable by a control unit of the magnetic resonance imaging device via an actuation connection.

16. The spine coil of claim 13, wherein the second portion is higher in a vertical direction than the second portion.

17. The spine coil of claim 3, wherein a height of the first housing is between 1 cm and 15 cm on an inside or an outside thereof.

18. The spine coil of claim 2, wherein the spine coil is configured for application of transmission power to individual transmission coil elements of the plurality of transmission coil elements, and wherein a switching of a transmitter apparatus to a respective transmission coil element of the plurality of transmission coil elements is provided by (a) actuating the transmitter apparatus belonging to the respective transmission coil element, (b) actuating a transmitter switching matrix integrated in the spine coil, or (c) actuating the transmitter apparatus belonging to the respective coil element and actuating the transmitter switching matrix integrated in the spine coil.

19. The spine coil of claim 1, wherein the spine coil is configured to be detuned, such that a magnetic resonance imaging device may be operated using only a body coil as a transmission coil.

20. The spine coil of claim 1, wherein the at least one transmission coil element comprises a loop/butterfly combination, and wherein the loop/butterfly combination is fed from a transmitter via a power divider, a phase shifter, or the power divider and the phase shifter.

21. The spine coil of claim 1, wherein the at least one transmission coil element is (a) configured to transmit radiofrequency signals for generating a B1 field, (b) connected to, or configured to be connected to, a transmission apparatus for generating radiofrequency signals, or (c) configured to transmit radiofrequency signals for generating the B1 field and connected to, or configured to be connected to, the transmission apparatus.

22. A magnetic resonance imaging device comprising a spine coil, wherein the spine coil comprises at least one transmission coil element configured for transmission.

23. A method for transmitting signals using a spine coil of a magnetic resonance imaging device, the spine coil comprising at least one transmission coil element configured for transmission, the method comprising:
transmitting signals by the at least one transmission coil element of the spine coil.

24. The spine coil of claim 7, wherein the spine coil is configured to split transmission power transmitted by the common transmission cable to an individual transmission coil element of the plurality of transmission coil elements based on an amplitude and a phase within the spine coil.

25. The spine coil of claim 16, wherein the second portion is higher than the first portion in the vertical direction by an amount between 1 cm and 7 cm.
